(19) United States
(12) Patent Application Publication
(10) Pub. No.: US 2026/0323984 A1
(43) Pub. Date: Oct. 15, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: KeJing Yu, Kaohsiung City (TW); Ru-Shang Hsiao, Jhubei City (TW); Sheng Yu Lin, Taoyuan City (TW)

(73) Assignee: Taiwan Semiconductor Manufacturing Company, Ltd., Hsinchu (TW)

(21) Appl. No.: 19/173,873

(22) Filed: Apr. 9, 2025

(51) Int. Cl. H10D 30/00; H03B 29/00; H10D 30/01; H10D 30/43; H10D 62/10; H10D 62/13; H10D 62/834; H10D 64/01; H10D 64/27; H10D 84/83

(52) U.S. Cl. CPC H10D 30/503; H10D 30/014; H10D 30/0194; H10D 30/43; H10D 30/506; H10D 62/121; H10D 62/151; H10D 62/834; H10D 64/017; H10D 64/516; H10D 64/518; H10D 64/519; H10D 84/8311; H10D 84/832; H03B 29/00

(57) ABSTRACT

A method, includes: forming a semiconductor structure including a plurality of nanostructures, a sacrificial gate structure, a source feature, and a drain feature; implanting ions in top and bottom surfaces of the plurality of nanostructures in channel regions of nanostructures; removing the sacrificial gate structure wherein a thickness of a nanostructure becomes uneven; and forming a replacement gate structure around the nanostructures, wherein a combination of an interfacial layer (IL) of the replacement gate structure surrounding the nanostructure and a high K dielectric layer of the replacement gate structure surrounding the nanostructure has an uneven thickness.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram depicting an example semiconductor structure for outputting a noisy signal.

FIG. 2 is a flow chart depicting an example method of semiconductor fabrication including fabrication of multi-gate devices, in accordance with some embodiments.

FIGS. 3-4, 5A-5C, 6, 7A-7B, and 8-19, are schematic diagrams of a semiconductor structure at various stages of fabrication, in accordance with some embodiments.

FIG. 20 is a flow chart depicting an example method of semiconductor fabrication including fabrication of multi-gate devices, in accordance with some embodiments.

FIGS. 21-23, which illustrate a noise-generator device at various stages of fabrication, in accordance with some embodiments.

FIG. 24 is a top view of an example noise-generator device, in accordance with some embodiments.

FIGS. 25 and 26 are cross-sectional views of the noise-generator device of FIG. 24, in accordance with some embodiments.

FIG. 27 is a top view of an example noise-generator device, in accordance with some embodiments.

FIG. 28 is a top view of an example noise-generator device, in accordance with some embodiments.

FIGS. 29 and 30 are cross-sectional views of the noise-generator device of FIG. 28, in accordance with some embodiments.

FIG. 31 is a top view of an example noise-generator device, in accordance with some embodiments.

FIG. 32 is a top view of an example noise-generator device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

This scaling also increases the complexity of the IC process and fabrication. For example, as Integrated Circuit (IC) technology advances to smaller technology nodes, multi-gate devices have been introduced to improve gate control by increasing gate-channel coupling, reducing off-state current, and reducing short-channel effects (SCE-CHANNEL EFFECT). A multi-gate device generally refers to a device having gate structures or portions thereof disposed over more than one side of a channel region. Fin-LIKE FIELD EFFECT transistors (FinFETs) and multi-bridge-channel (MBC) transistors are examples of multi-gate devices that have become popular and promising candidates for high performance and low leakage applications. The raised channels (ELEVATED CHANNEL) of the FinFET are gate wrapped on more than one side (e.g., gate wraps the top and sidewalls of a “fin” of semiconductor material extending from the substrate). MBC transistors have a gate structure that may extend partially or fully around the channel region to provide access to the channel region on two or more sides. Because the gate structure of the MBC transistor surrounds the channel region, the MBC transistor may also be referred to as a surrounding gate transistor (surrounding gate transistor: SGT) or a surrounding Gate (GAA) transistor. The channel region of the MBC transistor may be formed from nanowires, nanoplates, other nanostructures, and/or other suitable structures. The shape of the channel region is also given the MBC transistor alternative name, e.g. a nanoplate transistor or nanowire transistor. While existing GAA transistors are generally adequate for their intended purpose, they are not satisfactory in all respects.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

The formation of MBC transistors includes the formation of a stack comprising a plurality of channel layers interleaved by a plurality of sacrificial layers over a substrate, wherein the sacrificial layers may be selectively removed to release the channel layers as channel members by a subsequent etching process. The top of the stack and substrate are patterned to form active regions. The patterned top of the substrate may be referred to as a mesa structure (mesa structure). A gate structure including a dielectric layer and a conductive layer is then formed to surround and overlie each of the channel members. After the source/drain features are formed, the gate structure and sacrificial layer may be replaced with a functional gate stack. However, in some cases, MBC transistors may suffer from current leakage near the mesa. For example, the functional gate stack not only surrounds channel members disposed above the substrate, but also directly engages mesa structures below those channel members, resulting in a strong leakage current flowing into the substrate.

When a periodic signal is applied to an input terminal (e.g., gate) of a transistor, the transistor may output at its output terminal (e.g., drain) an output periodic signal. For applications where a noise generator is sought, additional structure may be provided to generate a noisy signal.

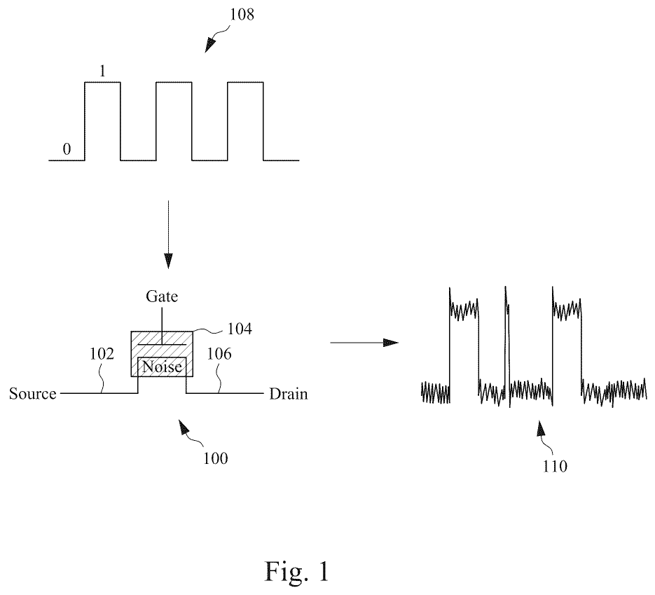

FIG. 1 is a schematic diagram depicting an example semiconductor structure for outputting a noisy signal. Depicted are an example noise-generator device 100 comprising a source terminal 102, a gate terminal 104, and a drain terminal 106. A periodic signal 108 is applied to the gate terminal 104 of the noise-generator device 100 and a noise signal 110 is output at the drain terminal. The example noise-generator device 100 can generate the noise signal 110 by a single transistor unit, instead of a complicated circuit design. The noise-generator device 100 is configured by noise implanting to damage one or more Si sheets in the channel region of the noise-generator device 100. The Si sheet damage can create Si sheet channel surface roughness. The Si sheet channel surface roughness can result in non-uniform interfacial layer (IL) / high-K (HK) dielectric layer deposition around the Si sheet channel during metal gate (MG) formation. The non-uniform interfacial layer (IL) / high-K (HK) dielectric layer deposited around the Si sheet channel can provide unexpected transistor inversion current, which results in the noise signal 110.

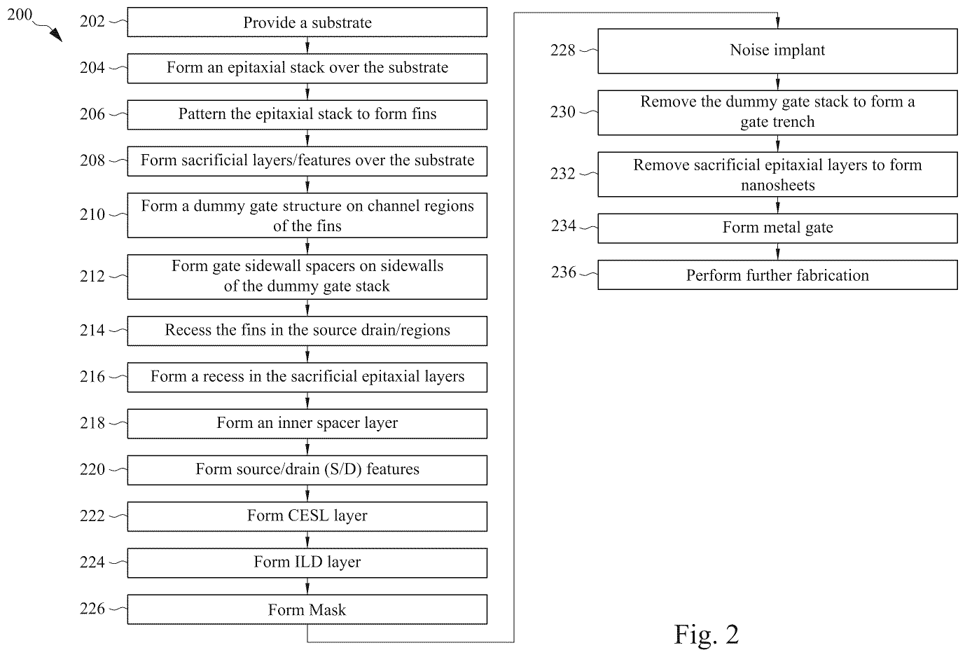

FIG. 2 is a flow chart depicting an example method 200 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

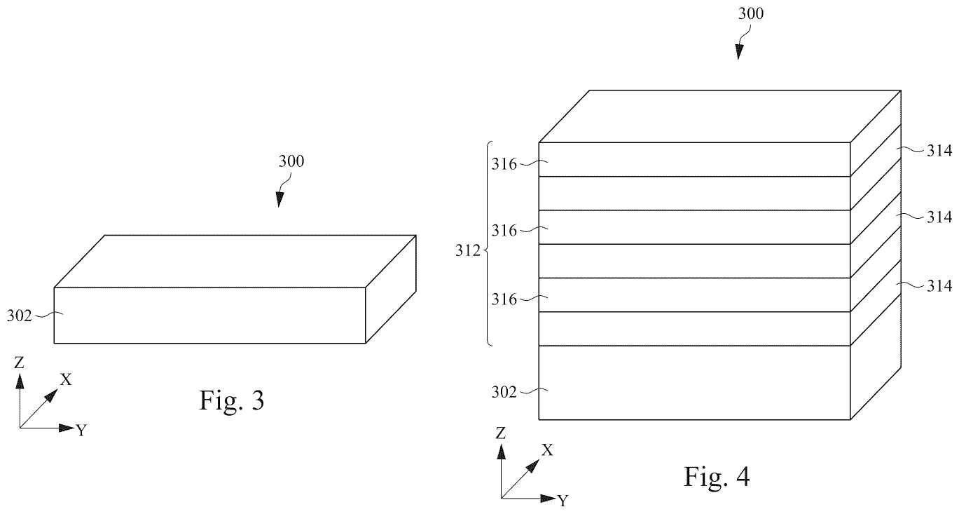

FIG. 2 is described in conjunction with FIGS. 3-4, 5A-5C, 6, 7A-7B, and 8-19, which illustrate a semiconductor device 300 or structure at various stages of fabrication in accordance with some embodiments. The method 200 is merely an example and is not intended to limit the present disclosure beyond what is explicitly recited in the claims. Additional steps may be provided before, during, and after method 200, and some of the steps described can be moved, replaced, or eliminated for additional embodiments of method 200. Additional features may be added in the semiconductor device 300 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 200, include any descriptions given with reference to the figures, as with the remainder of the method and exemplary figures provided in this disclosure, are merely exemplary and are not intended to be limiting beyond what is specifically recited in the claims that follow.

FIGS. 3-4, 5A-5C, 6, 7A-7B, and 8-19, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 202, the example method 200 includes providing a substrate. Referring to the example of FIG. 2, in an embodiment of block 202, a substrate 302 is provided for forming a semiconductor device 300. In some embodiments, the substrate 302 may be a semiconductor substrate such as a silicon (Si) substrate. In some embodiments, the substrate 302 includes a single crystalline semiconductor layer on at least its surface portion. The substrate 302 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 302 may include a compound semiconductor and/or an alloy semiconductor. The substrate 302 may include various layers, including conductive or insulating layers formed on a semiconductor substrate. The substrate 302 may include various doping configurations depending on design requirements. For example, different doping profiles (e.g., n wells, p wells) may be formed on the substrate 302 in regions designed for different device types (e.g., n-type field effect transistors (NFET), p-type field effect transistors (PFET)). The suitable doping may include ion implantation of dopants and/or diffusion processes. The substrate 302 has isolation features (e.g., shallow trench isolation (STI) features) interposing the regions providing different device types. Further, the substrate 302 may be strained for performance enhancement, may include a silicon-on-insulator (SOI) structure, and/or have other suitable enhancement features.

At block 204, the example method 200 includes forming an epitaxial stack that includes a plurality of epitaxial layers over the substrate. Referring to the example of FIG. 4, in an embodiment of block 204, an epitaxial stack 312 is formed over the substrate 302. The epitaxial stack 312 includes sacrificial epitaxial layers 314 of a first composition interposed by channel epitaxial layers 316 of a second composition. The first and second composition can be different. In an embodiment, the sacrificial epitaxial layers 314 are formed from SiGe and the channel epitaxial layers 316 are formed from silicon (Si). However, other embodiments are possible including those that provide for a first composition and a second composition having different oxidation rates and/or etch selectivity. In some embodiments, the sacrificial epitaxial layer 314 includes SiGe and the channel epitaxial layer 316 includes silicon (Si). However, other embodiments are possible including those that provide for a first composition and a second composition having different oxidation rates and/or etch selectivity. In some embodiments, the sacrificial epitaxial layer 314 includes SiGe and where the channel epitaxial layer 316 includes Si, the Si oxidation rate of the channel epitaxial layer 316 is less than the SiGe oxidation rate of the sacrificial epitaxial layer 314. It is noted that three (3) layers each of epitaxial layers 314 and 316 are illustrated in FIG. 4, which is for illustrative purposes only and not intended to be limiting beyond what is specifically recited in the claims. In various embodiments, any number of epitaxial layers can be formed in the epitaxial stack 312; the number of layers depending on the desired number of channel regions for the device 300. In some embodiments, the number of channel epitaxial layers 316 is between 1 and 5, such as 3, 4 or 5.

In some embodiments, the sacrificial epitaxial layer 314 has a thickness ranging from about 4 nm (nanometers) to about 12 nm. The sacrificial epitaxial layers 314 may be substantially uniform in thickness. In some embodiments, the channel epitaxial layer 316 has a thickness ranging from about 3 nm to about 6 nm. In some embodiments, the channel epitaxial layers 316 of the stack are substantially uniform in thickness.

As described in more detail below, the channel epitaxial layer 316 may serve as channel region(s) for a subsequently-formed multi-gate device and its thickness is chosen based on device performance considerations. The sacrificial epitaxial layer 314 may serve to reserve a spacing (or referred to as a gap) between adjacent channel region(s) for a subsequently-formed multi-gate device and its thickness is chosen based on device performance considerations.

By way of example, epitaxial growth of the epitaxial stack 312 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 316, include the same material as the substrate 302, such as silicon (Si). In some embodiments, the epitaxially grown layers 314 and 316 include a different material than the substrate 302. As stated above, in at least some examples, the sacrificial epitaxial layer 314 includes an epitaxially grown Si₁₋ₓGeₓ layer (e.g., x is about 25~55%) and the channel epitaxial layer 316 includes an epitaxially grown Si layer. Alternatively, in some embodiments, either of the sacrificial epitaxial layers 314 and channel epitaxial layers 316 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 314 and channel epitaxial layers 316 may be chosen based on providing differing oxidation and etch selectivity properties. In various embodiments, the epitaxial layers 314 and 316 are substantially dopant-free (i.e., having an extrinsic dopant concentration from about 0 cm⁻³ to about 1×10¹⁷ cm⁻³), where for example, no intentional doping is performed during the epitaxial growth process.

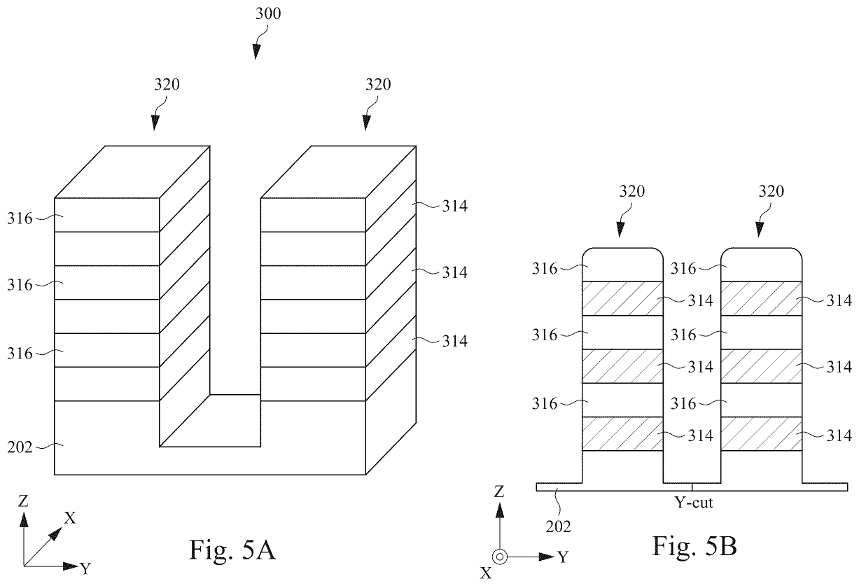

At block 206, the example method 200 includes patterning the epitaxial stack to form semiconductor fins (also referred to as fins). Referring to the example of FIGS. 5A, 5B, and 5C, in an embodiment of block 206, a plurality of fins 320 extending from the substrate 302 are formed. In various embodiments, each of the fins 320 includes an upper portion of the interleaved epitaxial layers 314 and 316 and a bottom portion protruding from the substrate 302.

The fins 320 may be fabricated using suitable processes including photolithography and etch processes. The photolithography process may include forming a photoresist layer over the substrate 302 (e.g., over the epitaxial stack 312), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 302, and epitaxial stack 312 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

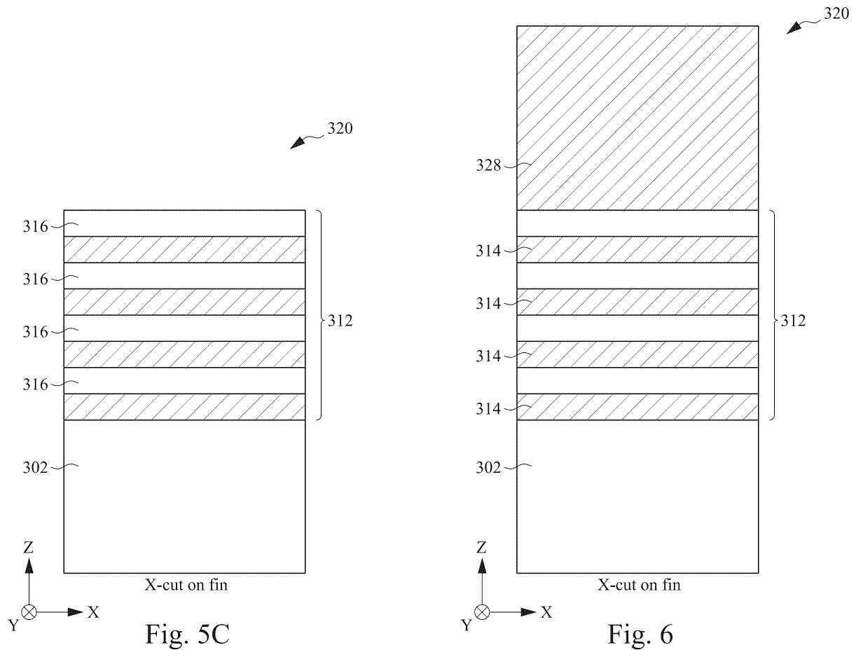

At block 208, the example method 200 includes forming one or more sacrificial layers/features over the substrate. Referring to the example of FIG. 6, in an embodiment of block 208, a sacrificial gate dielectric layer (not shown) is blanket deposited over a stop layer 322, which is formed over the fin 320, which is formed over the substrate 302. A sacrificial gate electrode layer 328 is then blanket deposited on the sacrificial gate dielectric layer and over the substrate 302. The sacrificial gate electrode layer 328 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 328 may be deposited using CVD, including LPCVD and PECVD, PVD, ALD, or other suitable processes.

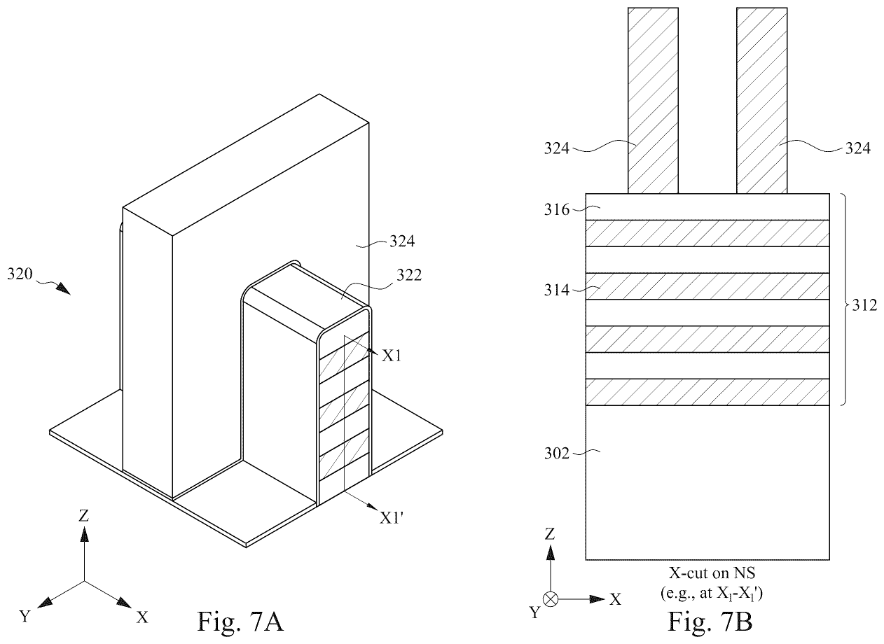

At block 210, the example method 200 includes patterning the one or more sacrificial layers/features to form a dummy gate structure on channel regions of the fins. Referring to the example of FIGS. 7A and 7B, in an embodiment of block 210, a sacrificial gate structure 324 is formed over portions of the fins 320 which are to be channel regions. The sacrificial gate structure 324 defines the channel regions of a GAA device. The sacrificial gate structure 324 includes a sacrificial gate dielectric layer and a sacrificial gate electrode layer 328. The sacrificial gate structure 324 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 324. By patterning the sacrificial gate structure 324, the fins 320 are partially exposed on opposite sides of the sacrificial gate structure 324, thereby defining source/drain (S/D) regions. In this disclosure, a source and a drain are interchangeably used, and the structures thereof are substantially the same.

The sacrificial gate structure 324 is subsequently removed as discussed with reference to block 230 of the method 200 and will be replaced by a final gate stack at a subsequent processing stage of the device 300. In particular, the sacrificial gate structure 324 is replaced at a later processing stage by a high-K dielectric layer (HK) and metal gate electrode (MG) as discussed below.

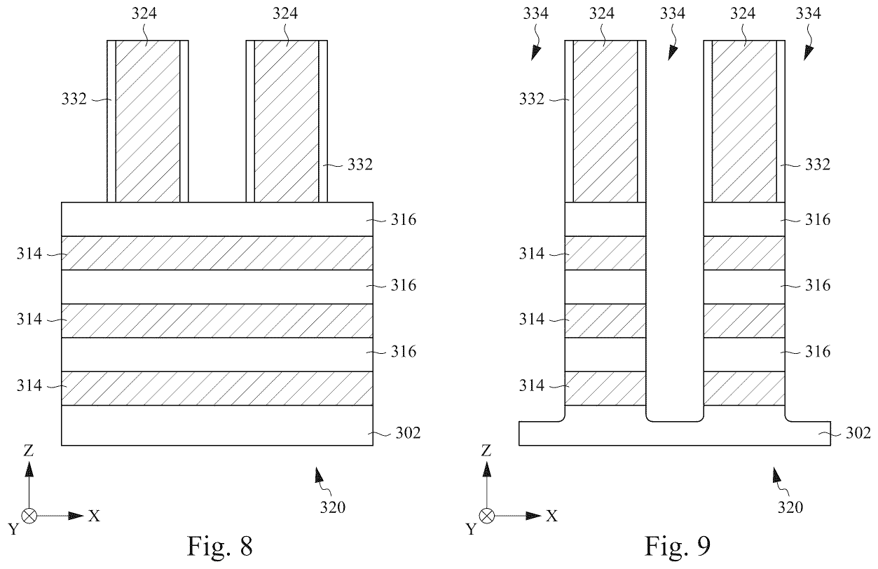

At block 212, the example method 200 includes forming gate sidewall spacers on sidewalls of the sacrificial gate structure. Referring to the example of FIG. 8, in an embodiment of block 212, gate sidewall spacers 332 are formed on sidewalls of the sacrificial gate structure 324. In various embodiments, the gate sidewall spacers 332 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 332 include multiple layers, such as main spacer walls, liner layers, and the like. By way of example, the gate sidewall spacers 332 may be formed by depositing a dielectric material layer over the sacrificial gate structure 324 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 320 adjacent to and not covered by the sacrificial gate structure 324 (e.g., S/D regions). The dielectric material layer may remain on the sidewalls of the sacrificial gate structure 324 as gate sidewall spacers 332. In some embodiments, the etching-back process may include a wet etch process, a dry etch process, a multiple-step etch process, and/or a combination thereof. The gate sidewall spacers 332 may have a thickness ranging from about 5 nm to about 20 nm.

At block 214, the example method includes recessing the fins in the source drain/regions. Referring to the example of FIG. 9, in an embodiment of block 214, the fin 320 is recessed in the source drain/regions. The stacked epitaxial layers 314 and 316 are etched down at the S/D regions to form a recess 334. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF₄, SF₆, CH₂F₂, CHF₃, and/or C₂F₆), other suitable gases, or combinations thereof.

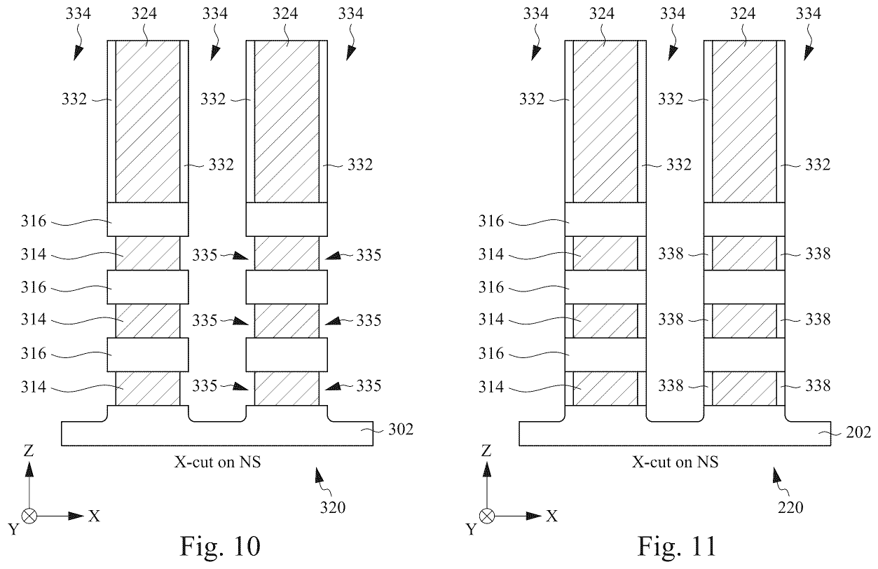

At block 216, the example method 200 includes forming a recess in the sacrificial epitaxial layers (e.g., SiGe) of the epitaxial stack. Referring to the example of FIG. 10, in an embodiment of block 216, the sacrificial epitaxial layers 314 have been etched back forming sacrificial epitaxial layer recesses 335 bounded on the top and bottom by channel epitaxial layers 316 and laterally by the recessed sacrificial epitaxial layers 314. The sacrificial epitaxial layers 314 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 218 lateral ends of the sacrificial epitaxial layers 314 that are exposed in the recess 334 may be selectively oxidized to increase the etch selectivity between the epitaxial layers 314 and 316. In some examples, the oxidation process may be performed by exposing the device 300 to a wet oxidation process, a dry oxidation process, or a combination thereof.

At block 218, the example method 200 Includes forming an inner spacer layer in the sacrificial epitaxial layer recesses. Forming the inner spacer layer may include depositing inner spacer material of a first material type in the sacrificial epitaxial layer recesses, and trimming the inner spacer layers (e.g., via etching operations). Referring to the example of FIG. 11, in an embodiment of block 218, inner spacer layers 338 are formed in the sacrificial epitaxial layer recesses 335. The inner spacer layers 338 may be formed from silicon oxides, silicon nitrides, silicon carbides, silicon carbide nitride, silicon oxide carbide, silicon carbide oxynitride, and/or other suitable dielectric materials. In some embodiments, the inner spacer layer 338 is deposited as a conformal layer. The inner spacer layers 338 can be formed by ALD or any other suitable method. In various embodiments, the inner spacer layers 338 are formed from the same material as the gate sidewall spacers 332. In various embodiments, the gate sidewall spacers 332 and the inner spacer layers 338 are formed from SiOCN.

At block 220, the example method 200 Includes forming source/drain (S/D) features. Forming the S/D features may involve depositing pure silicon in the recess 334 in the source drain/regions. In various embodiments, recessing the fins in the S/D regions may involve over etching the fins in the S/D regions wherein some of the substrate 302 below the height level of the bottom sacrificial epitaxial layer 314 is removed to prevent SiGe residue. Pure Si may be deposited in the recess 334 to raise the height of the substrate 302 below the recess 334 to the height level of the bottom sacrificial epitaxial layer 314.

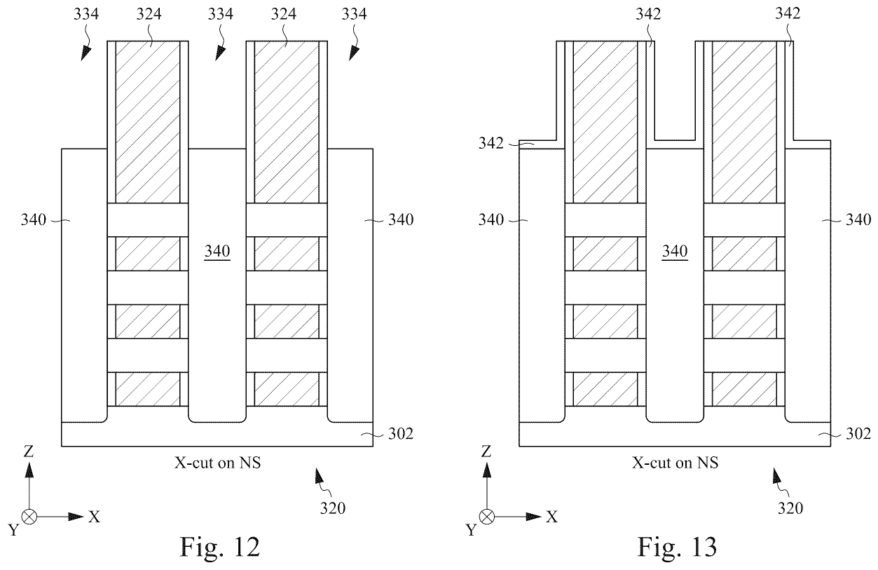

Referring to the example of FIG. 12, in an embodiment of block 220, epitaxial S/D features 340 are formed in recess 334. In some embodiments, the epitaxial S/D features 340 include silicon for NFETs and SiGe for PFETs. In some embodiments, the epitaxial S/D features 340 are formed by an epitaxial growth method using CVD, ALD, or molecular beam epitaxy (MBE). The epitaxial S/D features 340 are formed in contact with the channel epitaxial layers 316 and separated from the sacrificial epitaxial layers 314 by the inner spacer layers 338.

At block 222, the example method 200 includes forming a CESL layer. Referring to the example of FIG. 13, in an embodiment of block 224, a contact etch stop (CESL) layer 342 is formed over the S/D features 340. The CESL layer 342 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 342 is formed from SiN.

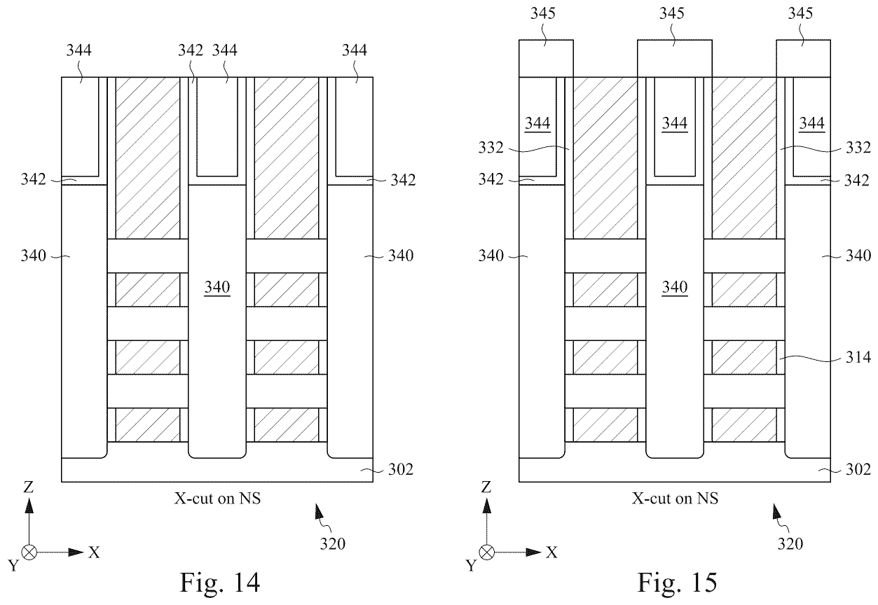

At block 224, the example method 200 includes forming an ILD layer. Referring to the example of FIG. 14, in an embodiment of block 224, an interlayer dielectric layer (ILD layer 344) is formed over the CESL layer 342. The ILD layer 344 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 344 may be formed by PECVD, flowable CVD (FCVD), or other suitable methods. In some embodiments, forming the ILD layer 344 further includes performing a CMP process to planarize a top surface of the device 300, such that the top surfaces of the sacrificial gate structure 324 are exposed.

At block 226, the example method 200 includes forming a mask over the gate sidewall spacers 332, CESL layer 342, and the ILD layer 344. Referring to the example of FIG. 15, in an embodiment of block 226, a mask 345 is formed over the gate sidewall spacers 332, CESL layer 342, and the ILD layer 344

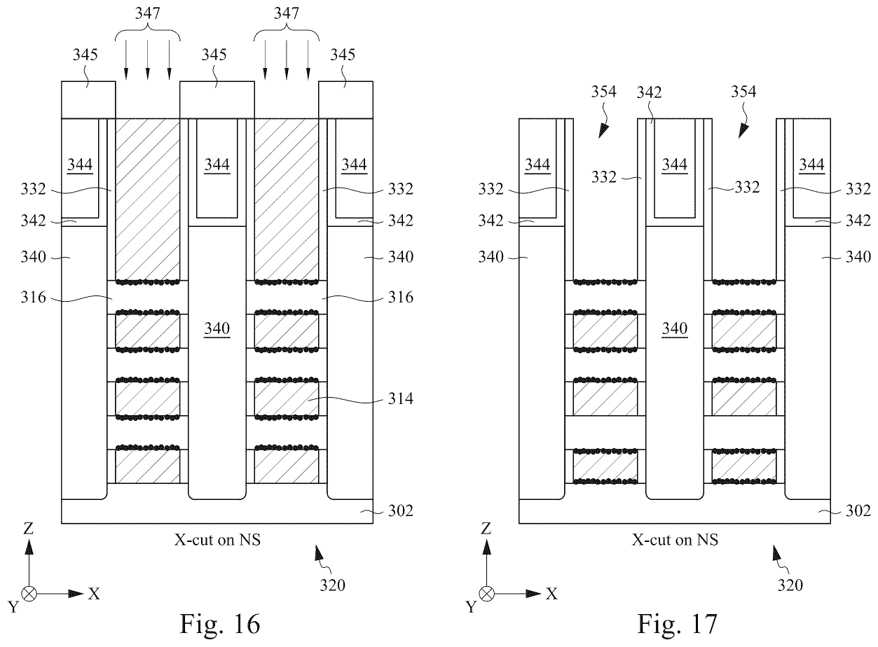

At block 228, the example method 200 includes implanting a noise inducing element that damages the channel epitaxial layers. Referring to the example of FIG. 16, in an embodiment of block 228, a noise inducing element 347, such as Xe, Ge, Ar, or He ions, are implanted at the top and bottom surfaces of the channel epitaxial layers 316.

At block 230, the example method 200 includes removing the dummy gate stack to form a gate trench. Referring to the example of FIG. 17, in an embodiment of block 230, the sacrificial gate structure 324 has been removed to form a gate trench 354. The gate trench 354 exposes the fin 320 in the channel region(s). The ILD0 layer 344 and the CESL layer 342 protects the epitaxial S/D features 340 during the removal of the sacrificial gate structure 324. The sacrificial gate structure 324 can be removed using plasma dry etching and/or wet etching. When the sacrificial gate electrode layer is polysilicon and the ILD0 layer 344 is an oxide, a wet etchant such as a TMAH solution can be used to selectively remove the sacrificial gate electrode layer. The sacrificial gate dielectric layer is thereafter removed using plasma dry etching and/or wet etching.

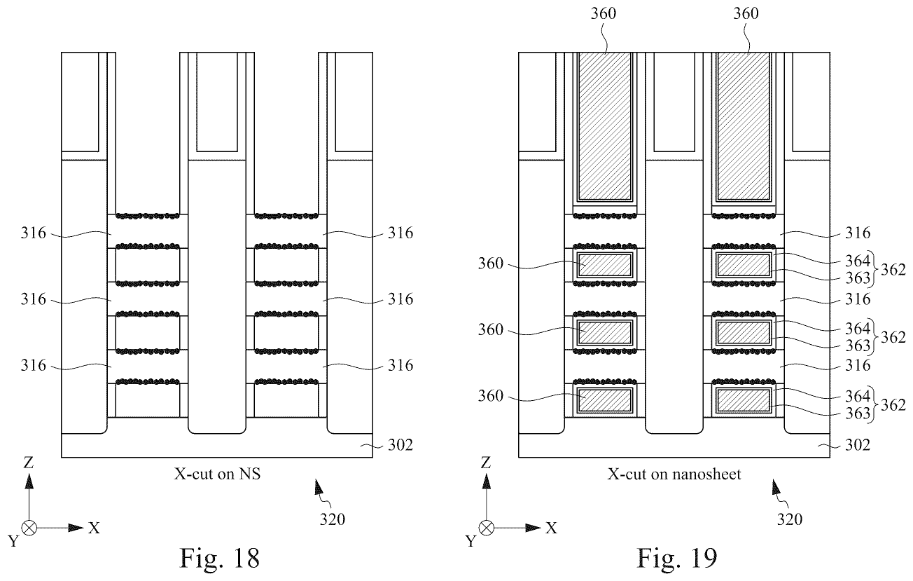

At block 232, the example method 200 includes removing the sacrificial epitaxial layers to form nanosheets. Referring to the example of FIG. 18, in an embodiment of block 232, sacrificial epitaxial layers 314 have been removed thereby releasing channel members from the channel region of the GAA device. In the illustrated embodiment, channel members are channel epitaxial layers 316 in the form of nanosheets. In various embodiments, the channel epitaxial layers 316 include silicon, and the sacrificial epitaxial layers 314 include silicon germanium. In various embodiments, the plurality of sacrificial epitaxial layers 314 were selectively removed via a selective removal process that included oxidizing the plurality of sacrificial epitaxial layers 314 using a suitable oxidizer, such as ozone. Thereafter, the oxidized sacrificial epitaxial layers 314 were selectively removed via a dry etching process, for example, by applying an HCl gas at a temperature of about 500 degrees Celsius to about 700 degrees Celsius, or applying a gas mixture of CF₄, SF₆, and CHF₃.

At block 234, the example method 200 includes forming metal gate structures. Referring to the example of FIG. 19, in an embodiment of block 234, a gate structure 360 is formed. In various embodiments, the gate structure 360 is the gate of a multi-gate transistor. In various embodiments, the gate structure 360 is a high-K metal gate stack, however other compositions are possible. In various embodiments the high-K metal gate stack includes a gate dielectric layer 362 that includes an interfacial layer 363 and a high-k dielectric layer 364. The high-k dielectric layer 364 wraps each of the nanosheets 316, and the interfacial layer 363 is interposed between the high-k dielectric layer and the nanosheets 316. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

At block 236, the example method 200 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be replaced or eliminated in accordance with various embodiments of the method 200.

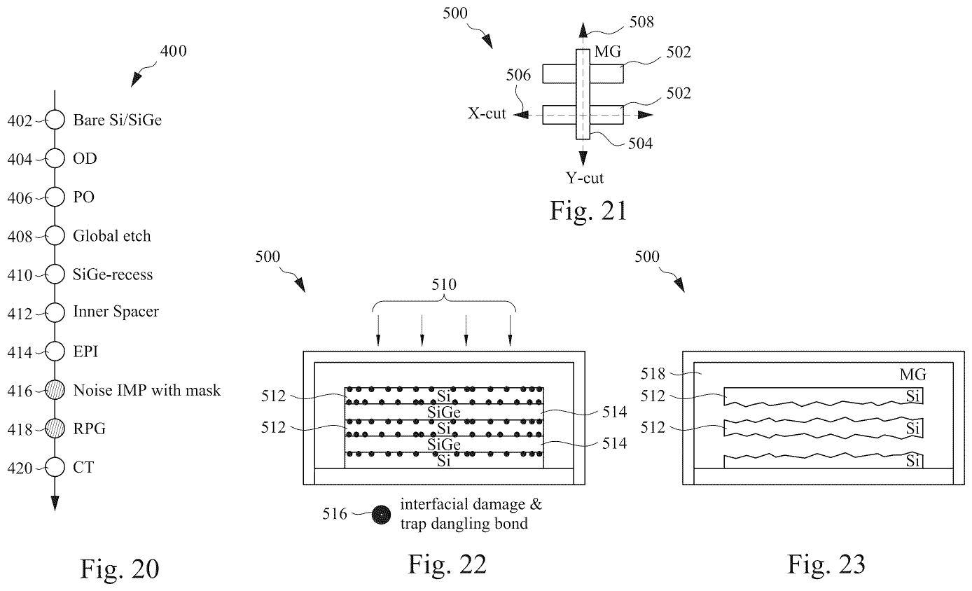

FIG. 20 is a flow chart depicting an example method 400 of semiconductor fabrication including fabrication of multi-gate devices, according to various aspects of the present disclosure. FIG. 20 is described in conjunction with FIGS. 21-23, which illustrate a noise-generator device 500 at various stages of fabrication in accordance with some embodiments. The method 400 is merely an example and is not intended to limit the present disclosure beyond what is explicitly recited in the claims. Additional steps may be provided before, during, and after method 400, and some of the steps described can be moved, replaced, or eliminated for additional embodiments of method 400. Additional features may be added in the noise-generator device 500 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 402, the example method 400 includes providing an epitaxial stack that includes a plurality of epitaxial layers over a substrate. This block is similar to blocks 202 and 204 of method 200 and reference is made to the corresponding description of blocks 202 and 204 for example description of block 402.

At block 404, the example method 400 includes forming an active region of a semiconductor structure. This block is similar to block 206 of method 200 and reference is made to the corresponding description of block 206 for example description of block 404.

At block 406, the example method 400 includes forming a sacrificial gate structure over the portions of the active region. This block is similar to blocks 208, 210 and 212 of method 200 and reference is made to the corresponding description of blocks 208, 210 and 212 for example description of block 406.

At block 408, the example method 400 includes recessing the fins in the source drain/regions. This block is similar to block 214 of method 200 and reference is made to the corresponding description of block 214 for example description of block 408.

At block 410, the example method 400 includes forming a recess in the sacrificial epitaxial layers (e.g., SiGe) of the epitaxial stack. This block is similar to block 216 of method 200 and reference is made to the corresponding description of block 216 for example description of block 410.

At block 412, the example method 400 Includes forming an inner spacer layer in the sacrificial epitaxial layer recesses. This block is similar to block 218 of method 200 and reference is made to the corresponding description of block 218 for example description of block 412.

At block 414, the example method 400 Includes forming source/drain (S/D) features. This block is similar to blocks 220, 222, and 224 of method 200 and reference is made to the corresponding description of blocks 220, 222, and 224 for example description of block 414.

At block 416, the example method 400 Includes performing a noise implant in the silicon sheets. This block is similar to blocks 226 and 228 of method 200 and reference is made to the corresponding description of block 222 for example description of block 416.

Referring to the example of FIGS. 21-22, FIG. 21 is a top view of the example noise-generator device 500. The example noise-generator device 500 includes a plurality of active areas 502 and a metal gate 504 over portions of the active areas 502. Also depicted are a X-cut line 506 and a Y-cut line 508. FIG. 22 is a cross-sectional view of an embodiment of the noise-generator device 500 at block 416. Implantation elements 510 comprising, for example, Xe or Ge, are implanted in the nanosheets 512 at boundaries with sacrificial layers 514, which cause damage 516 (e.g., interfacial damage and trap dangling bond formation) at top and/or bottom faces of the nanosheets 512. In various embodiments, the implantation elements 510 are implanted in a plasma chamber by injecting Xe, Ge, Ar, or He ions into the target (Si sheets). In various embodiments, the ions are implanted with high energy/current/concentration to allow the ions to penetrate into the Si channel and cause interfacial damage or trap dangling bond.

At block 418, the example method 400 Includes performing replacement metal gate operations. This block is similar to blocks 230, 232, and 234 of method 200 and reference is made to the corresponding description of blocks 230, 232, and 234 for example description of block 418. Because of the damage 516 to the nanosheets 512, portions of the nanosheets 512 on top and bottom surfaces break away during dummy gate stack and sacrificial epitaxial layer removal operations (e.g., during wet etching to remove the dummy gate stack and sacrificial epitaxial layers) leaving the nanosheets 512 with rough, as opposed to smooth, top and bottom surfaces. Because of the rough top and bottom surfaces, during metal gate formation operations, non-uniform IL and HK dielectric layers are deposited on the rough top and bottom surfaces of the nanosheets 512.

At block 420, the example method 400 includes performing further fabrication. A semiconductor device may undergo further processing to form various features and regions known in the art.

Referring to the example of FIGS. 21-22, FIG. 23 is a cross-sectional view of an embodiment of the noise-generator device 500 at block 418. As depicted, the nanosheets 512 have rough top and/or bottom surfaces, and the IL and HK dielectric layers of the gate structure 518 are formed on the rough top and bottom surfaces of the nanosheets 512. During operation of the noise-generator device 500, the non-uniform channel width, non-uniform IL thickness, and/or the non-uniform HK dielectric thickness contribute to provide an unexpected transistor inversion current and flicker noise, which yields a noise signal as an output.

In various embodiments, the non-uniform channel width is due to a top surface of a nanosheet 512 having an uneven thickness and a bottom surface of a nanosheet 512 having an uneven thickness. In various embodiments, a combination of an interfacial layer (IL) of the gate structure 518 surrounding the nanosheet 512 and a high K dielectric layer of the gate structure 518 surrounding the nanosheet 512 has an uneven thickness. In various embodiments, an interfacial layer (IL) of the gate structure 518 surrounding the nanosheet 512 has an uneven thickness and/or a high K dielectric layer of the gate structure 518 surrounding the nanosheet 512 has an uneven thickness. In various embodiments, the nanosheet 512 has a thickness deviation of greater than 5%.

A noise-generator device may take on a number of different configurations. In one embodiment, the noise-generator device includes an active region having a curved shape from a top view and includes a plurality of gate structures of stacked nanosheets.

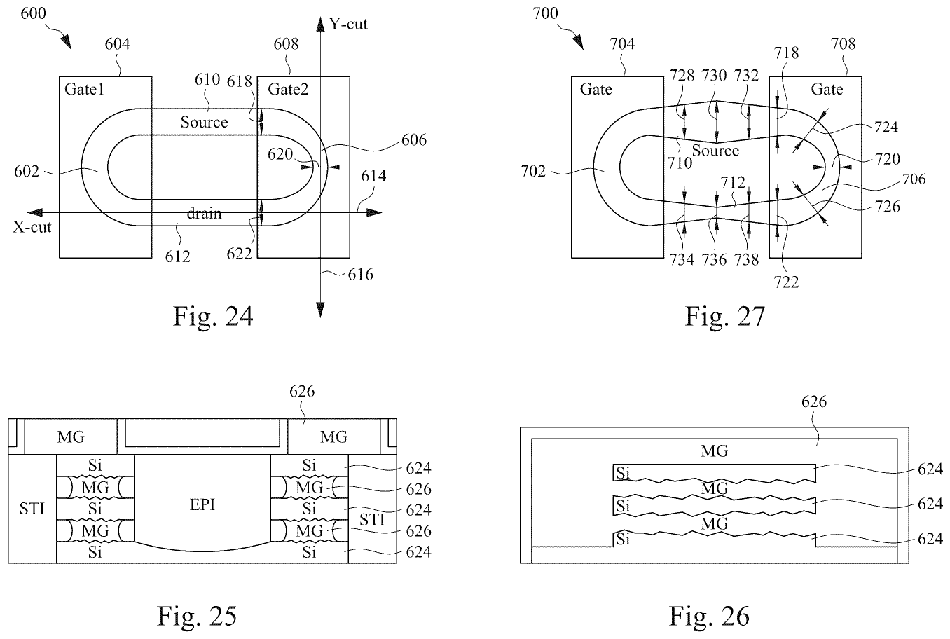

FIG. 24 is a top view of an example noise-generator device 600. The noise-generator device 600 includes an active region comprising a first channel region 602 surrounded by a first gate structure 604 and a second channel region 606 surrounded by a second gate structure 608. The active region further includes a source region 610 disposed between a first end of the first channel region 602 and a first end of the second channel region 606, and a drain region 612 disposed between a second end of the first channel region 602 and a second end of the second channel region 606. Each of the first channel region 602 and the second channel region 606 has a curved shape from a top view. FIG. 24 also includes an X-cut line 614 and a Y-cut line 616.

In the disclosed embodiment, the second channel region 606 has a varying width including a first width 618 near the source region 610, a second width 620 near the middle of the second channel region 606, and a third width 622 near the drain region 612. In this embodiment, the second width 620 is smaller than the first width 618 and the third width 622. In some embodiments, the first width 618 is different from the third width 622. In some embodiments, the second width 620 may be larger than the first width 618 and the third width 622. In some embodiments, the first channel region 602 may have widths that are different from widths of the second channel region 606. The non-uniform width of the closed shape layout can achieve current crowding and induce noise channel current.

FIG. 25 is a cross-sectional view of the noise-generator device 600 along the X-cut line 614, and FIG. 26 is a cross-sectional view of the noise-generator device 600 along the Y-cut line 616. These figures illustrate that the noise-generator device 600 includes nanosheet structures 624 that have rough top and/or bottom surfaces. The IL and HK dielectric layers of the gate structure 626 are formed on the rough top and bottom surfaces of the nanosheet structures 624. During operation of the noise-generator device 600, the non-uniform channel width, non-uniform IL thickness, and/or the non-uniform HK dielectric thickness contribute to provide an unexpected transistor inversion current and flicker noise, which yields a noise signal as an output.

In various embodiments, the non-uniform channel width is due to a top surface of a nanosheet structure 624 having an uneven thickness and a bottom surface of a nanosheet structure 624 having an uneven thickness. In various embodiments, a combination of an interfacial layer (IL) of the gate structure 626 surrounding the nanosheet structure 624 and a high K dielectric layer of the gate structure 626 surrounding the nanosheet structure 624 has an uneven thickness. In various embodiments, an interfacial layer (IL) of the gate structure 626 surrounding the nanosheet structure 624 has an uneven thickness and/or a high K dielectric layer of the gate structure 626 surrounding the nanosheet structure 624 has an uneven thickness. In various embodiments, the nanosheet structure 624 has a thickness deviation of greater than 5%.

FIG. 27 is a top view of an example noise-generator device 700. The noise-generator device 700 includes an active region comprising a first channel region 702 surrounded by a first gate structure 704 and a second channel region 706 surrounded by a second gate structure 708. The active region further includes a source region 710 disposed between a first end of the first channel region 702 and a first end of the second channel region 706, and a drain region 712 disposed between a second end of the first channel region 702 and a second end of the second channel region 706.

In the disclosed embodiment, the second channel region 706 has a varying width including a first width 718 near the source region 710, a second width 720 near the middle of the second channel region 706, a third width 722 near the drain region 712, a fourth width 724 between the first width 718 and the second width 720, and a fifth width 726 between the second width 720 and the third width 722. In this embodiment, the first width 718 is greater than the fourth width 724, the fourth width 724 is greater than the second width 720, the second width 720 is smaller than the fifth width 726, and the 726 is smaller than the third width 722. In some embodiments, the first width 718, the second width 720, the third width 722, the fourth width 724, and the fifth width 726 are all different. In some embodiments, some of the widths may have the same size. In some embodiments, the first channel region 602 may have widths that are different from widths of the second channel region 606.

In the disclosed embodiment, the source region 710 has a varying width including a sixth width 728 near the first gate structure 704, a seventh width 730 near the middle of the source region 710, and an eighth width 732 near the drain region 712. In this embodiment, the seventh width 730 is larger than the sixth width 728 and the eighth width 732. In some embodiments, the seventh width 730 may be smaller than the sixth width 728 and the eighth width 732.

In the disclosed embodiment, the drain region 712 has a varying width including a ninth width 734 near the first gate structure 704, a tenth width 736 near the middle of the drain region 712, and an eleventh width 738 near the drain region 712. In this embodiment, the tenth width 736 is smaller than the ninth width 734 and the eleventh width 738. In some embodiments, the tenth width 736 may be larger than the ninth width 734 and the eleventh width 738. The non-uniform width of the closed shape layout can achieve current crowding and induce noise channel current.

A cross-sectional view of the noise-generator device 700 in the x-direction, and a cross-sectional view of the noise-generator device 700 in a y-direction would show that the noise-generator device 700 includes nanosheets that have rough top and bottom surfaces. IL and HK dielectric layers of a metal gate are formed on the rough top and bottom surfaces of the nanosheets. During operation of the noise-generator device 700, the non-uniform channel width, non-uniform IL thickness, and/or the non-uniform HK dielectric thickness contribute to provide an unexpected transistor inversion current and flicker noise, which yields a noise signal as an output.

In various embodiments, the non-uniform channel width is due to a top surface of a nanosheet structure having an uneven thickness and a bottom surface of a nanosheet structure having an uneven thickness. In various embodiments, a combination of an interfacial layer (IL) of the gate structure surrounding the nanosheet structure and a high K dielectric layer of the gate structure surrounding the nanosheet structure has an uneven thickness. In various embodiments, an interfacial layer (IL) of the gate structure surrounding the nanosheet structure has an uneven thickness and/or a high K dielectric layer of the gate structure surrounding the nanosheet structure has an uneven thickness. In various embodiments, the nanosheet structure has a thickness deviation of greater than 5%.

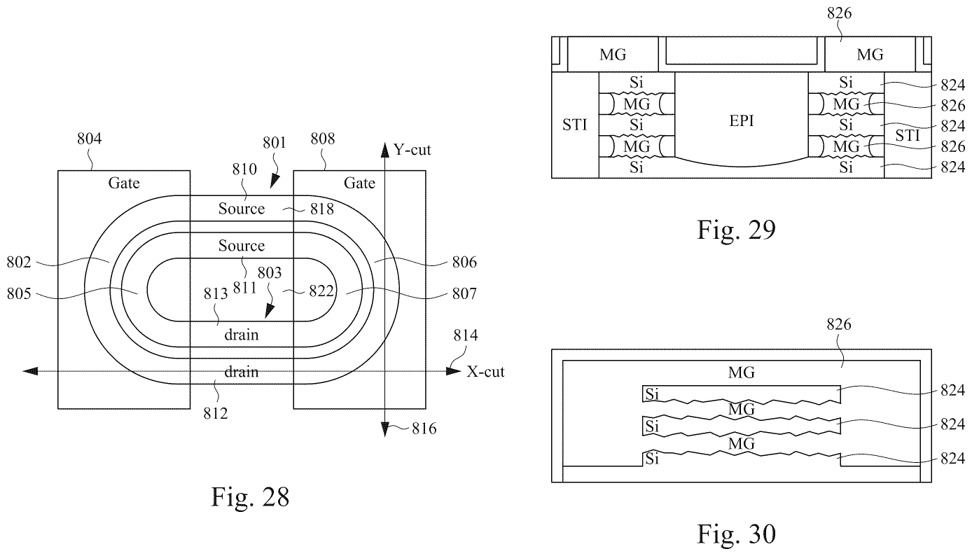

FIG. 28 is a top view of an example noise-generator device 800. The noise-generator device 800 includes a first active region 801 having a closed shape layout from a top view and comprising a first channel region 802 surrounded by a first gate structure 804 and a second channel region 806 surrounded by a second gate structure 808. The first active region 801 further includes a first source region 810 disposed between a first end of the first channel region 802 and a first end of the second channel region 806, and a first drain region 812 disposed between a second end of the first channel region 802 and a second end of the second channel region 806. Each of the first channel region 802 and the second channel region 806 has a curved shape from a top view. In various embodiments, the first active region 801 may have varying widths, for example, as illustrated above with regard to FIGS. 24 and 27. The non-uniform width of the closed shape layout can achieve current crowding and induce noise channel current.

The noise-generator device 800 further includes a second active region 803 having a closed shape layout from a top view comprising a third channel region 805 surrounded by the first gate structure 804 and a fourth channel region 807 surrounded by the second gate structure 808. The second active region 803 further includes a second source region 811 disposed between a first end of the third channel region 805 and a first end of the fourth channel region 807, and a second drain region 813 disposed between a second end of the third channel region 805 and a second end of the fourth channel region 807. Each of the third channel region 805 and the fourth channel region 807 has a curved shape from a top view. The second active region 803 is disposed between the first active region 801. In various embodiments, the second active region 803 may have varying widths, for example, as illustrated above with regard to FIGS. 24 and 27. The non-uniform width of the closed shape layout can achieve current crowding and induce noise channel current.

FIG. 28 also includes an X-cut line 814 and a Y-cut line 816. FIG. 29 is a cross-sectional view of the noise-generator device 800 along the X-cut line 814, and FIG. 30 is a cross-sectional view of the noise-generator device 800 along the Y-cut line 816. These figures illustrate that the noise-generator device 800 includes nanosheet structures 824 that have rough top and/or bottom surfaces. The IL and HK dielectric layers of the gate structure 826 are formed on the rough top and bottom surfaces of the nanosheet structures 824. During operation of the noise-generator device 800, the non-uniform channel width, non-uniform IL thickness, and/or the non-uniform HK dielectric thickness contribute to provide an unexpected transistor inversion current and flicker noise, which yields a noise signal as an output.

In various embodiments, the non-uniform channel width is due to a top surface of a nanosheet structure 824 having an uneven thickness and a bottom surface of a nanosheet structure 824 having an uneven thickness. In various embodiments, a combination of an interfacial layer (IL) of the gate structure 826 surrounding the nanosheet structure 824 and a high K dielectric layer of the gate structure 826 surrounding the nanosheet structure 824 has an uneven thickness. In various embodiments, an interfacial layer (IL) of the gate structure 826 surrounding the nanosheet structure 824 has an uneven thickness and/or a high K dielectric layer of the gate structure 826 surrounding the nanosheet structure 824 has an uneven thickness. In various embodiments, the nanosheet structure 824 has a thickness deviation of greater than 5%.

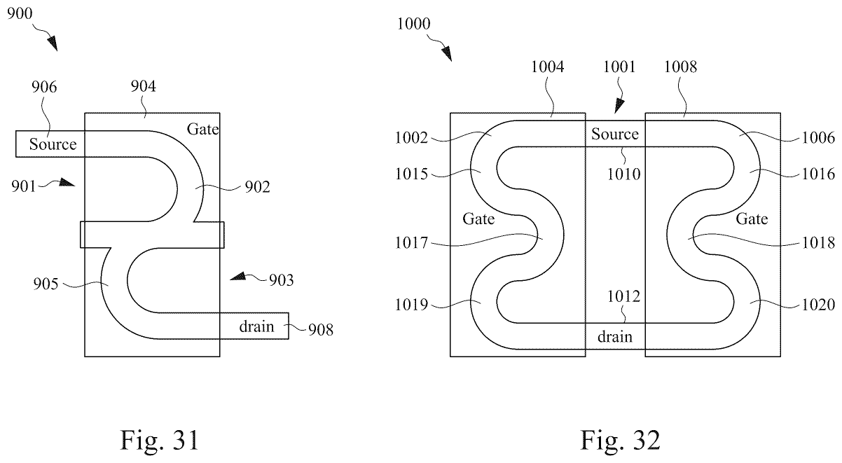

FIG. 31 is a top view of an example noise-generator device 900. The noise-generator device 900 includes a first active region 901 having an open shape layout from a top view and comprising a first channel region 902 surrounded by a gate structure 904. The first active region 901 further includes a source region 906 disposed on a first end of the first channel region 902. The first channel region 902 has a curved shape from a top view. In various embodiments, the first active region 901 may have varying widths, for example, as illustrated above with regard to FIGS. 24 and 27. The non-uniform width of the open shape layout can achieve current crowding and induce noise channel current.

The noise-generator device 900 further includes a second active region 903 having an open shape layout from a top view comprising a second channel region 905 surrounded by the gate structure 904. The second active region 903 further includes a drain region 908 disposed on a second end of the second channel region 905. The second channel region 905 has a curved shape from a top view. The second channel region 905 overlaps with the first channel region 902. In various embodiments, the second active region 903 may have varying widths, for example, as illustrated above with regard to FIGS. 24 and 27. The non-uniform width of the open shape layout can achieve current crowding and induce noise channel current.

A cross-sectional view of the noise-generator device 900 in the x-direction, and a cross-sectional view of the noise-generator device 900 in a y-direction would show that the noise-generator device 900 includes nanosheets that have rough top and bottom surfaces. IL and HK dielectric layers of a metal gate are formed on the rough top and bottom surfaces of the nanosheets. During operation of the noise-generator device 900, the non-uniform channel width, non-uniform IL thickness, and/or the non-uniform HK dielectric thickness contribute to provide an unexpected transistor inversion current and flicker noise, which yields a noise signal as an output.

In various embodiments, the non-uniform channel width is due to a top surface of a nanosheet structure having an uneven thickness and a bottom surface of a nanosheet structure having an uneven thickness. In various embodiments, a combination of an interfacial layer (IL) of the gate structure surrounding the nanosheet structure and a high K dielectric layer of the gate structure surrounding the nanosheet structure has an uneven thickness. In various embodiments, an interfacial layer (IL) of the gate structure surrounding the nanosheet structure has an uneven thickness and/or a high K dielectric layer of the gate structure surrounding the nanosheet structure has an uneven thickness. In various embodiments, the nanosheet structure has a thickness deviation of greater than 5%.

FIG. 32 is a top view of an example noise-generator device 1000. The noise-generator device 1000 includes an active region 1001 having a closed shape layout from a top view and comprising a first channel region 1002 surrounded by a first gate structure 1004, a second channel region 1006 surrounded by a second gate structure 1008, a source region 1010 disposed between a first end of the first channel region 1002 and a first end of the second channel region 1006, and a drain region 1012 disposed between a second end of the first channel region 1002 and a second end of the second channel region 1006. The first channel region 1002 has a curved shape from a top view with a plurality of curved regions (three in this example-curved region 1015, curved region 1017, and curved region 1019), and the second channel region 1006 has a curved shape from a top view with a plurality of curved regions (three in this example-curved region 1016, curved region 1018, and curved region 1020). In various embodiments, the active region 1001 may have varying widths, for example, as illustrated above with regard to FIGS. 24 and 27. The non-uniform width of the closed shape layout can achieve current crowding and induce noise channel current.

A cross-sectional view of the noise-generator device 1000 in the x-direction, and a cross-sectional view of the noise-generator device 1000 in a y-direction would show that the noise-generator device 1000 includes nanosheets that have rough top and bottom surfaces. IL and HK dielectric layers of a metal gate are formed on the rough top and bottom surfaces of the nanosheets. During operation of the noise-generator device 1000, the non-uniform channel width, non-uniform IL thickness, and/or the non-uniform HK dielectric thickness contribute to provide an unexpected transistor inversion current and flicker noise, which yields a noise signal as an output.

In various embodiments, the non-uniform channel width is due to a top surface of a nanosheet structure having an uneven thickness and a bottom surface of a nanosheet structure having an uneven thickness. In various embodiments, a combination of an interfacial layer (IL) of the gate structure surrounding the nanosheet structure and a high K dielectric layer of the gate structure surrounding the nanosheet structure has an uneven thickness. In various embodiments, an interfacial layer (IL) of the gate structure surrounding the nanosheet structure has an uneven thickness and/or a high K dielectric layer of the gate structure surrounding the nanosheet structure has an uneven thickness. In various embodiments, the nanosheet structure has a thickness deviation of greater than 5%.

In some aspects, the techniques described herein relate to a semiconductor structure, including: a channel region including a plurality of stackedly spaced nanostructures wherein a first nanostructure of the plurality of stackedly spaced nanostructures has an uneven thickness; and a gate structure surrounding the plurality of stackedly spaced nanostructures, wherein an interfacial layer (IL) of the gate structure surrounds the first nanostructure and a high K dielectric layer of the gate structure surrounds the first nanostructure.

In some aspects, the techniques described herein relate to a semiconductor structure, further including an active region including the channel region, a source region, and a drain region, wherein the active region includes a closed shape layout from a top view.

In some aspects, the techniques described herein relate to a semiconductor structure, wherein the channel region includes a first channel region of the plurality of stackedly spaced nanostructures and a second channel region of the plurality of stackedly spaced nanostructures.

In some aspects, the techniques described herein relate to a semiconductor structure, wherein the first channel region has a varying width including: a first width near a source region; a second width near a middle of the channel region; and a third width near a drain region; wherein the second width is different from the first width and the third width.

In some aspects, the techniques described herein relate to a semiconductor structure, wherein the first width is different from the third width.

In some aspects, the techniques described herein relate to a semiconductor structure, wherein the second width larger than the first width and the third width.

In some aspects, the techniques described herein relate to a semiconductor structure, wherein the first channel region has varying widths that are different from widths of the second channel region.

In some aspects, the techniques described herein relate to a semiconductor structure, further including a first active region and a second active region, wherein: the first active region includes an open shape layout from a top view; the second active region includes an open shape layout from the top view; and the channel region includes a first channel region with a curved shape from a top view in the first active region and a second channel region with a curved shape from a top view in the second active region; and at least one of the first active region and the second active region has varying widths.

In some aspects, the techniques described herein relate to a semiconductor structure, wherein a combination of the IL and the high K dielectric layer has an uneven thickness.

In some aspects, the techniques described herein relate to a method, including: forming a semiconductor structure including a plurality of nanostructures, a sacrificial gate structure, a source feature, and a drain feature; implanting ions in top and bottom surfaces of the plurality of nanostructures in channel regions of nanostructures; removing the sacrificial gate structure wherein a thickness of a nanostructure structure becomes uneven; and forming a replacement gate structure around the nanostructures.

In some aspects, the techniques described herein relate to a method, wherein the nanostructure structure has a thickness deviation of greater than 5 percent.

In some aspects, the techniques described herein relate to a method, wherein the ions include Xe, Ge, Ar, or He ions.

In some aspects, the techniques described herein relate to a method, wherein removing the sacrificial gate structure includes performing wet etch operations, and the nanostructure has a surface roughness after the wet etch operations.

In some aspects, the techniques described herein relate to a method, wherein forming the semiconductor structure includes forming the plurality of nanostructures with varying widths.

In some aspects, the techniques described herein relate to a method, wherein forming the semiconductor structure includes forming the source feature with varying widths.

In some aspects, the techniques described herein relate to a method, wherein forming the semiconductor structure includes forming the drain feature with varying widths.

In some aspects, the techniques described herein relate to a noise-generator structure, including: a first active region including a closed shape layout from a top view, wherein the first active region includes a first channel region, a second channel region, a first source region, and a first drain region, the first channel region includes a plurality of stackedly spaced nanostructures surrounded by a first gate structure, and the second channel region includes the plurality of stackedly spaced nanostructures surrounded by a second gate structure, the first source region is disposed between a first end of the first channel region and a first end of the second channel region, and the first drain region disposed between a second end of the first channel region and a second end of the second channel region; wherein the first active region has varying widths in at least one of the first channel region, the second channel region, the first source region, and the first drain region.

In some aspects, the techniques described herein relate to a noise-generator structure, further including: a second active region including a third channel region surrounded by the first gate structure; a fourth channel region surrounded by the second gate structure; a second source region disposed between a first end of the third channel region and a first end of the fourth channel region; a second drain region disposed between a second end of the third channel region and a second end of the fourth channel region; and the second active region including a closed shape layout from a top view; wherein the second active region having varying widths in at least one of the third channel region, the fourth channel region, the second source region, and the second drain region.

In some aspects, the techniques described herein relate to a noise-generator structure, further including: the first channel region having a curved shape from a top view with a plurality of curved regions; and the second channel region having a curved shape from a top view with a plurality of curved regions.

In some aspects, the techniques described herein relate to a noise-generator structure, further including: a first nanosheet structure of the plurality of stackedly spaced nanosheet structures having an uneven thickness; and a combination of an interfacial layer (IL) and a high K dielectric layer surrounding the first nanosheet structure of at least one of the first gate structure or the second gate structure having an uneven thickness.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor structure, comprising:
a channel region comprising a plurality of stackedly spaced nanostructures wherein a first nanostructure of the plurality of stackedly spaced nanostructures has an uneven thickness; and
a gate structure surrounding the plurality of stackedly spaced nanostructures, wherein an interfacial layer (IL) of the gate structure surrounds the first nanostructure and a high K dielectric layer of the gate structure surrounds the first nanostructure.

2. The semiconductor structure of claim 1, further comprising an active region comprising the channel region, a source region, and a drain region, wherein the active region comprises a closed shape layout from a top view.

3. The semiconductor structure of claim 1, wherein the channel region comprises a first channel region of the plurality of stackedly spaced nanostructures and a second channel region of the plurality of stackedly spaced nanostructures.

4. The semiconductor structure of claim 3, wherein the first channel region has a varying width including:
a first width near a source region;
a second width near a middle of the channel region; and
a third width near a drain region;
wherein the second width is different from the first width and the third width.

5. The semiconductor structure of claim 4, wherein the first width is different from the third width.

6. The semiconductor structure of claim 4, wherein the second width larger than the first width and the third width.

7. The semiconductor structure of claim 3, wherein the first channel region has varying widths that are different from widths of the second channel region.

8. The semiconductor structure of claim 1, further comprising a first active region and a second active region, wherein:
the first active region comprises an open shape layout from a top view;
the second active region comprises an open shape layout from the top view;
the channel region comprises a first channel region with a curved shape from a top view in the first active region and a second channel region with a curved shape from a top view in the second active region; and
at least one of the first active region and the second active region has varying widths.

9. The semiconductor structure of claim 1, wherein a combination of the IL and the high K dielectric layer has an uneven thickness.

10. A method, comprising:
forming a semiconductor structure comprising a plurality of nanostructures, a sacrificial gate structure, a source feature, and a drain feature;
implanting ions in top and bottom surfaces of the plurality of nanostructures in channel regions of nanostructures;
removing the sacrificial gate structure wherein a thickness of a nanostructure structure becomes uneven; and
forming a replacement gate structure around the nanostructures.

11. The method of claim 10, wherein the nanostructure structure has a thickness deviation of greater than 5 percent.

12. The method of claim 10, wherein the ions comprise Xe, Ge, Ar, or He ions.

13. The method of claim 10, wherein removing the sacrificial gate structure comprises performing wet etch operations, and the nanostructure has a surface roughness after the wet etch operations.

14. The method of claim 10, wherein forming the semiconductor structure comprises forming the plurality of nanostructures with varying widths.

15. The method of claim 10, wherein forming the semiconductor structure comprises forming the source feature with varying widths.

16. The method of claim 10, wherein forming the semiconductor structure comprises forming the drain feature with varying widths.

17. A noise-generator structure, comprising:
a first active region comprising a closed shape layout from a top view, wherein:
the first active region comprises a first channel region, a second channel region, a first source region, and a first drain region,
the first channel region comprises a plurality of stackedly spaced nanostructures surrounded by a first gate structure, and the second channel region comprises the plurality of stackedly spaced nanostructures surrounded by a second gate structure,
the first source region is disposed between a first end of the first channel region and a first end of the second channel region, and
the first drain region disposed between a second end of the first channel region and a second end of the second channel region;
wherein the first active region has varying widths in at least one of the first channel region, the second channel region, the first source region, and the first drain region.

18. The noise-generator structure of claim 17, further comprising:
a second active region comprising a third channel region surrounded by the first gate structure;
a fourth channel region surrounded by the second gate structure;
a second source region disposed between a first end of the third channel region and a first end of the fourth channel region;
a second drain region disposed between a second end of the third channel region and a second end of the fourth channel region; and
the second active region comprising a closed shape layout from a top view;
wherein the second active region having varying widths in at least one of the third channel region, the fourth channel region, the second source region, and the second drain region.

19. The noise-generator structure of claim 17, further comprising:
the first channel region having a curved shape from a top view with a plurality of curved regions; and
the second channel region having a curved shape from a top view with a plurality of curved regions.

20. The noise-generator structure of claim 17, further comprising:
a first nanostructure of the plurality of stackedly spaced nanostructures having an uneven thickness; and
a combination of an interfacial layer (IL) and a high K dielectric layer surrounding the first nanostructure of at least one of the first gate structure or the second gate structure having an uneven thickness.
